(19) United States
(12) Patent Application Publication
(10) Pub. No.: US 2025/0149414 A1
(43) Pub. Date: May 8, 2025

(54) LOW Z-HEIGHT SEPARABLE LIQUID METAL BASED ELECTRICAL INTERCONNECT

(71) Applicant: Intel Corporation, Santa Clara, CA (US)

(72) Inventors: Ziyin LIN, Chandler, AZ (US); Karumbu MEYYAPPAN, Portland, OR (US); Gregorio R. MURTAGIAN, Phoenix, AZ (US); Dingying David XU, Chandler, AZ (US)

(21) Appl. No.: 18/504,352

(22) Filed: Nov. 8, 2023

(51) Int. Cl. H01L 23/498; H01L 23/00

(52) U.S. Cl. CPC H01L 23/49811; H01L 23/49866; H01L 24/16; H01L 24/32; H01L 24/73; H01L 2224/16225; H01L 2224/32225; H01L 2224/73253

(57) ABSTRACT

Embodiments disclosed herein include an interconnect structure. In an embodiment, the interconnect structure is an apparatus that comprises a substrate with a well through a thickness of the substrate. In an embodiment, the substrate comprises a polymer foam. In an embodiment, a liquid metal is in the opening, and the liquid metal comprises voids.

### BACKGROUND

Second level interconnect (SLI) architectures are used in order to mechanically and electrically couple a board (e.g., a motherboard) to a package substrate. SLI architectures may include ball grid array (BGA) approaches that include solder balls between the board and the package substrate. Such architectures are difficult to remove and replace. A more flexible approach is to use socket based technologies. When a replacement is needed, the sockets can be removed and one or more components can be repaired or replaced. One particular type of socket that enables even easier replacement (i.e., re-socketing) uses liquid metal arrays. The liquid metal array includes wells that are filled with the liquid metal. The pins are then inserted into the well to make the necessary electrical connection.

However, such liquid metal socket solutions may suffer from poor electrical performance in some situations. For example, the pins of the socket may need to be long in order to account for warpage of the package substrate and/or the board. The length of the pins not only reduces the benefit of low resistance capabilities attributable to the liquid metal, but also introduces challenges with high-speed IO applications. Further, increased Z-height attributable to the pins may be a limiting factor for some use cases.

### BRIEF DESCRIPTION OF THE DRAWINGS

FIG. 1A is a cross-sectional illustration of an electronic system with a liquid metal based pin array for the second level interconnect (SLI), in accordance with an embodiment.

FIG. 1B is a cross-sectional illustration of an electronic system with a liquid metal carrier array (LMCA) that does not use pins, in accordance with an embodiment.

FIG. 2A is a cross-sectional illustration of a portion of an LMCA with a well that is partially filled with a liquid metal, in accordance with an embodiment.

FIG. 2B is a cross-sectional illustration of a portion of an LMCA after the substrate is compressed and the liquid metal protrudes out from the well, in accordance with an embodiment.

FIG. 2C is a cross-sectional illustration of a portion of an LMCA after the substrate is compressed without reducing a width of the well, in accordance with an embodiment.

FIG. 2D is a cross-sectional illustration of a portion of an LMCA after the substrate and the liquid metal are compressed, in accordance with an embodiment.

FIG. 3A is a cross-sectional illustration of an open cell foam that can be used as the substrate for an LMCA, in accordance with an embodiment.

FIG. 3B is a cross-sectional illustration of a liquid metal with voids that allows for the liquid metal to be compressed, in accordance with an embodiment.

FIG. 4A is a cross-sectional illustration of an electronic system that includes an LMCA with a compressible substrate and a compressible liquid metal, in accordance with an embodiment.

FIG. 4B is a cross-sectional illustration of an electronic system that includes an LMCA that is compressed without decreasing a width of the wells, in accordance with an embodiment.

FIGS. 5A-5J are cross-sectional illustrations depicting a process for forming an LMCA with a low Poisson's ratio substrate and a compressible liquid metal, in accordance with an embodiment.

FIG. 6A is a cross-sectional illustration of an electronic system that includes an LMCA with an adhesive and a standoff feature, in accordance with an embodiment.

FIG. 6B is a cross-sectional illustration of the electronic system in FIG. 6A after the LMCA is compressed, in accordance with an embodiment.

FIG. 7A is a cross-sectional illustration of an LMCA with protective layers over and under the substrate, in accordance with an embodiment.

FIG. 7B is a cross-sectional illustration of a board with an LMCA attached, in accordance with an embodiment.

FIG. 7C is a cross-sectional illustration of an electronic system with an LMCA for the SLI, in accordance with an embodiment.

FIG. 8 is a schematic of a computing device built in accordance with an embodiment.

### EMBODIMENTS OF THE PRESENT DISCLOSURE

Described herein are electronic systems, and more particularly, liquid metal carrier arrays with compressible polymer and liquid metal materials, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

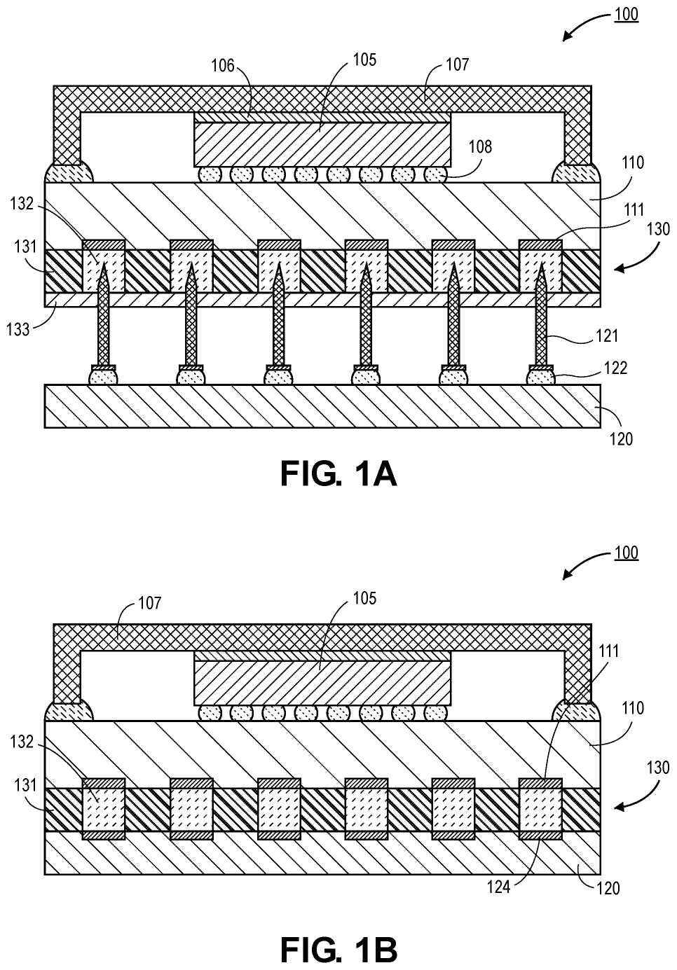

As noted above, existing socketing technologies that use liquid metal carrier arrays (LMCAs) for second level interconnect (SLI) applications rely on pins to couple the board to the package substrate. The pins are attached to the board (e.g., with solder) and extend into a well of the LMCA that is filled with a liquid metal. The liquid metal contacts a pad on the package substrate in order to make the electrical connection between the board and the package substrate. However, due to warpage (of the board and/or the package substrate) the pins need to be long. For example, pins may have a Z-height of approximately 2.0 mm or more. This negatively impacts the electrical performance and increase the overall Z-height of the electronic system. One such electronic system 100 is shown in FIG. 1A.

As shown, the electronic system 100 includes a board 120, such as a motherboard. Pins 121 are coupled to the board 120 through solder 122 or the like. The pins 121 may be inserted into an LMCA 130. Particularly, the pins 121 pass through a cover 133 and into a well within a substrate 131. The well is filled with a liquid metal 132. The liquid metal contacts a pad 111 on the bottom of the package substrate 110. In an embodiment, one or more dies 105 may be coupled to the package substrate 110 through first level interconnects (FLIs), such as solder balls 108 or the like. The die 105 may be coupled to a heat spreader 107 or other thermal solution through a thermal adhesive 106.

As shown, the pins 121 occupy a substantial portion of the Z-height. Accordingly, some embodiments have been proposed that eliminate the use of the pins 121. An example of such a solution is shown in FIG. 1B. As shown, the pins 121 are omitted and the LMCA 130 is provided between the package substrate 110 and the board 120. For example, the liquid metal 132 may directly contact the pads 124 on the board 120 and the pads 111 on the package substrate 110.

Unfortunately, such simple substitution is not without issue. Particularly, the substrate 131 of the LMCA 130 will be compressed in order to make good electrical contact between the pads 111 and the pads 124. The compression (in the Z-direction) leads to expansion of the substrate 131 in the X and Y directions. This will cause the diameter (or width) of the wells to shrink. As such, the liquid metal is extruded out of the wells. This may result in electrical shorting between pads 111 and/or between pads 124. Since the liquid metal 132 is substantially non-compressible, this extrusion issue is magnified.

Accordingly, embodiments disclosed herein leverage material selection of the features of the LMCA in order to mitigate extrusion of the liquid metal. In one embodiment, the substrate is made from a low Poisson's ratio material. The Poisson's ratio is a measure of how much the material expands laterally when compressed vertically. Poisson's ratios of 0.3 to 0.5 (or greater) are typical for many materials used for LMCA substrates (e.g., elastomers, such as silicone).

In embodiments disclosed herein, the substrate of the LMCA is formed with a material that has a Poisson's ratio of 0.2 or lower, 0.1 or lower, or even 0. For example, a compression of the substrate by up to approximately 40% in the Z-direction may result in a minimal change in the width of the well through the substrate. As used herein, “minimal change” or “substantially no change” may refer to a well width for a compressed substrate (i.e., up to approximately 60% compression) that is between approximately 90% and 100% or approximately 95% and 100% of the well width for an uncompressed substrate.

Low Poisson's ratio materials may include polymer foam materials. For example, the polymer foams may include elastomeric foams, such as a silicone foam. In an embodiment, the foam may be an open cell foam. A volume percentage of air in the substrate material may be approximately 80% or greater, approximately 90% or greater, or approximately 95% or greater. As used herein, “approximately” may refer to a range of values within ten percent of the stated value. For example, approximately 90% may refer to a range between 81% and 99%.

The second feature of the LMCA that can be controlled to improve performance is the liquid metal. Typically, liquid metals are substantially non-compressible. In order to enable compression, embodiments include doping the liquid metal with a gas, such as air. The gas doping results in the formation of voids within the volume of the liquid metal. The voids allow for some degree of compression that limits liquid metal extrusion. For example, the voids may account for up to approximately 50% of the liquid metal by volume. In some instances, the voids may account for between approximately 20% and approximately 50% of the liquid metal by volume.

In an embodiment, the liquid metal may be any metal or metal alloy that exhibits a liquid phase a room temperature. For example, the liquid metal may be in the liquid phase at temperatures down to approximately 0° C., or down to approximately −25° C. Liquid metals disclosed herein may comprise indium and/or gallium, either of which may be combined with various amounts of alloying elements, such as tin.

The use of a compressible LMCA with a compressible liquid metal offers low Z-height, separable, and room temperature bonding. This enables various applications useful for a wide range of packages. For example, in co-packaged optics where some components are temperature sensitive, such an LMCA enables easy replacement during the device lifecycle. Similarly, memories can be placed in close proximity to the processor while remaining easily replaceable and reconfigurable.

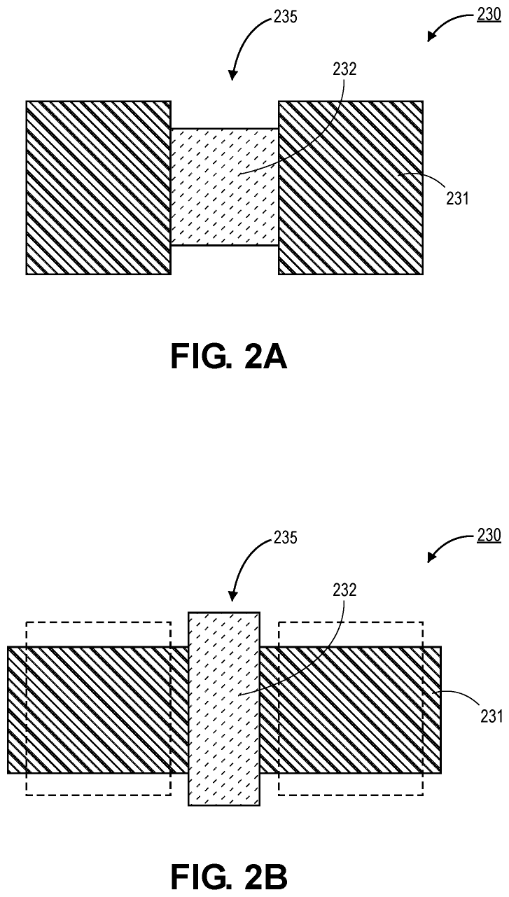

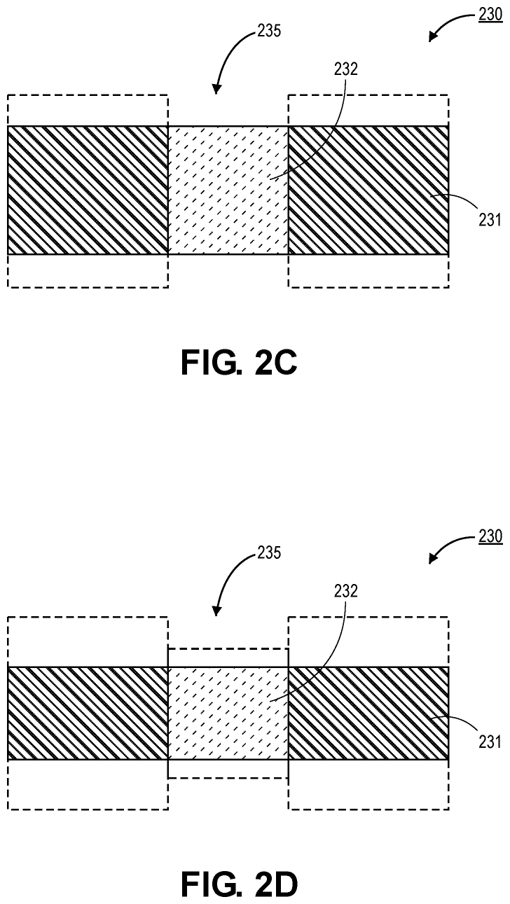

Referring now to FIG. 2A, a cross-sectional illustration of a portion of an LMCA 230 is shown, in accordance with an embodiment. The LMCA 230 may comprise a substrate 231. The substrate 231 may be a polymer material that is compressible. For example, the substrate 231 may be an elastomeric material. A well 235 (also sometimes referred to as an opening) may pass through a thickness of the substrate 231. The well 235 may have substantially vertical sidewalls in some embodiments. The well 235 may be any shape. For example, the well 235 may have a circular shape, a rectangular shape, or any other shape (when viewed in a plan view from above). In an embodiment, the well 235 may have a width or diameter that is substantially constant through a thickness of the substrate 231.

In an embodiment, the LMCA 230 may further comprise a liquid metal 232 that is disposed in the well 235. The volume of the liquid metal 232 may be less than a volume of the well 235. This allows for some degree of compression of the substrate 231 without the risk of liquid metal 232 extrusion. The liquid metal 232 may comprise an alloy that is in the liquid phase around room temperature. For example, the liquid metal 232 may comprise indium, gallium, and/or any other suitable alloying elements.

Referring now to FIG. 2B, a cross-sectional illustration of an LMCA 230 without a low Poisson's ratio substrate 231 after compression is shown, in accordance with an embodiment. In FIG. 2B, the dashed lines indicate the geometry of the substrate 231 before compression. As shown, compressing the substrate 231 in the Z-direction results in lateral expansion (in the X-direction and/or the Y-direction). Stated another way, when the substrate 231 is a high Poisson's ratio material (such as silicone) compression in one dimension results in expansion in another dimension. This causes restriction of the well 235. That is, the width of the well 235 is decreased compared to the width of the well 235 before vertical compression. Accordingly, the liquid metal 232 may extrude beyond the confines of the well 235. As such, excess liquid metal 232 may spread over the surfaces of the substrate 231, and can potentially lead to shorting to neighboring liquid metal regions (not shown). This extrusion phenomenon is made worse since the liquid metal 232 is generally not compressible either.

Referring now to FIG. 2C, a cross-sectional illustration of an LMCA 230 is shown, in accordance with an alternative embodiment. In the embodiment shown in FIG. 2C, the substrate 231 is a low Poisson's ratio material. For example, the Poisson's ratio of the substrate 231 may be up to approximately 0.2 or up to approximately 0.1. Examples of such materials are similar to those described in greater detail above. In one instance, the substrate 231 may comprise a polymer foam, such as an elastomeric foam. p The foam may be an open cell foam. Due to the low Poisson's ratio, vertical compression of the substrate 231 may result in minimal expansion horizontally. As such, a width of the well 235 when the substrate 231 is compressed may be substantially similar to the width of the well 235 when the substrate 231 is not compressed. That is, a well 235 width for a compressed substrate 231 may be between approximately 90% and 100% or between approximately 95% and 100% of the well 235 width for an uncompressed substrate 231. In an embodiment, the substrate 231 may be compressed up to approximately 40% in the vertical Z-direction without a substantial change in the well 235 width, or the substrate 231 may be compressed up to approximately 50% in the vertical Z-direction without a substantial change in the well 235 width.

Referring now to FIG. 2D, a cross-sectional illustration of a portion of an LMCA 230 is shown, in accordance with an additional embodiment. In the embodiment shown in FIG. 2D, the substrate 231 and the liquid metal 232 may both be compressible. The dashed lines in FIG. 2D represent the geometries of the substrate 231 and the liquid metal 232 in an uncompressed state. In an embodiment, the substrate 231 in FIG. 2D may be a low Poisson's ratio material similar to the one described above with respect to FIG. 2C. Accordingly, as the substrate 231 is compressed, the width of the well 235 remains substantially unchanged.

In an embodiment, the liquid metal 232 may be a gas doped liquid metal. The gas doping allows for the formation of voids within the volume of the liquid metal 232. During compression, the voids can reduce in volume in order to enable the bulk compression of the liquid metal 232. The liquid metal 232 may comprise up to approximately 50% voids (e.g., air) by volume, or between approximately 20% voids and approximately 50% voids by volume. Despite the presence of the voids, the liquid metal 232 still retains high electrical conductivity since there are still continuous metal paths through the liquid metal 232.

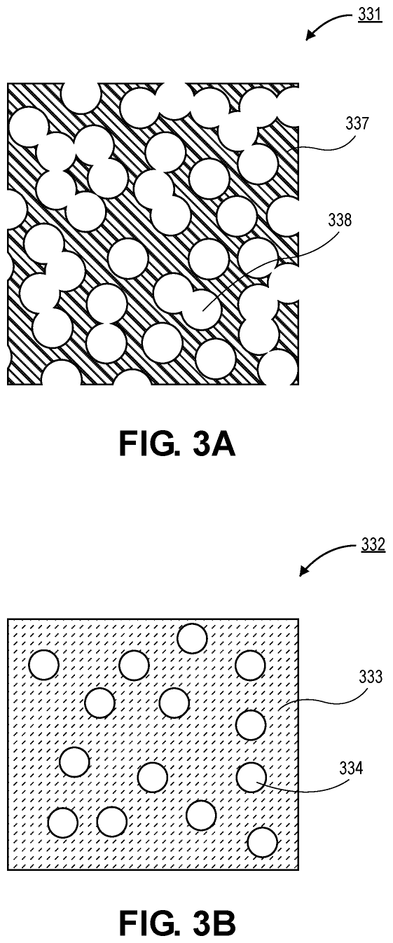

Referring now to FIG. 3A, a cross-sectional illustration of a portion of a substrate 331 in a LMCA is shown, in accordance with an embodiment. In an embodiment, the substrate 331 is a low Poisson's ratio material. For example, the Poisson's ratio of the substrate 331 may be up to approximately 0.2, or up to approximately 0.1. More generally, at small to moderate compression in the Z-direction (e.g., a compression of up to approximately 50% of the Z-direction thickness), the substrate 331 may undergo minimal (if any) horizontal expansion.

The substrate 331 may include a solid matrix 337. The solid matrix 337 may be a polymer. For example, the solid matrix 337 may be an elastomer, such as silicone or the like. In an embodiment, the cells 338 may be provided within the solid matrix 337. The cells 338 may be filled with air or another gas. The cells 338 may be considered as being in an open cell arrangement. That is, individual cells 338 may be connected together in order to provide larger air gaps within the solid matrix 337. The cells 338 may extend to the perimeter of the solid matrix 337. In an embodiment, the cells 338 may occupy 50% or more of the volume of the substrate 331, 80% or more of the volume of the substrate 331, or 95% or more of the volume of the substrate 331.

The diameter of the cells 338 may be small enough that the liquid metal (not shown in FIG. 3A) does not flow into the volume of the substrate 331. In addition to controlling a diameter of the cells 338, the surface energy of the liquid metal may prevent flow into the cells 338. That is, a high surface energy liquid metal will not tend to flow since larger amounts of energy are needed in order to induce the flow into the cells 338. However, if the cells 338 are too larger and/or if the surface energy is not high enough, a liner may be provided between the liquid metal and the substrate 331. An example of a liner embodiment will be described in greater detail below.

Referring now to FIG. 3B, a cross-sectional illustration of a portion of a compressible liquid metal 332 in an LMCA is shown, in accordance with an embodiment. The compressible liquid metal 332 may include an electrically conductive liquid 333 that remains in the liquid phase at and around room temperature. For example, the electrically conductive liquid 333 may be in the liquid phase at temperatures down to approximately 0° C. or down to approximately −25° C. For example, the electrically conductive liquid 333 may comprise indium and gallium. Other alloying elements may be provided along with indium and/or gallium, such as tin.

In an embodiment, the liquid metal 332 is compressible through the introduction of voids 334 into the volume of the electrically conductive liquid 333. The voids 334 may be air filled voids 334. Though, other gasses may also be provided within the voids 334. In an embodiment, the volume of the voids 334 within the electrically conductive liquid 333 may account for up to approximately 50% of the volume of the liquid metal 332. In some embodiments, the voids 334 may account for between approximately 20% and approximately 50% of the volume of the liquid metal 332.

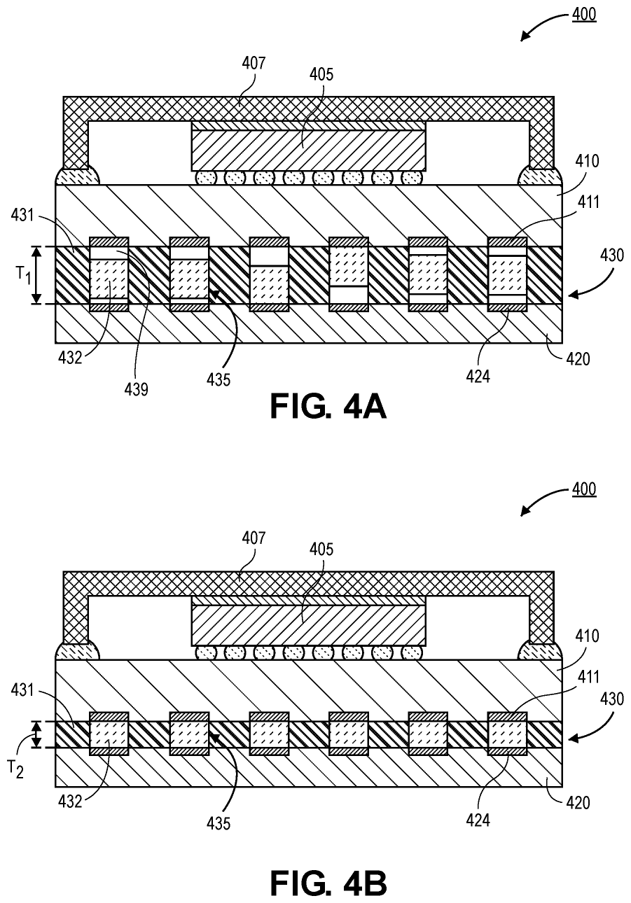

Referring now to FIGS. 4A and 4B, a pair of cross-sectional illustrations of an electronic system 400 with an uncompressed LMCA 430 (FIG. 4A) and a compressed LMCA 430 (FIG. 4B) is shown, in accordance with an embodiment.

Referring now to FIG. 4A, an electronic system 400 is shown, in accordance with an embodiment. In an embodiment, the electronic system 400 may include a board 420, such as a printed circuit board (PCB), a motherboard, or the like. The board 420 may include pads 424. In an embodiment, a package substrate 410 is provided over the board 420. The package substrate 410 may be any suitable package substrate 410 architecture, such as a cored package substrate 410 or a coreless package substrate 410. In the case of a cored package substrate 410, the core may be an organic core or a glass core. Organic buildup layers with electrically conductive routing (not shown) may be provided over and under the core.

In an embodiment, the pads 411 of the package substrate 410 may be electrically coupled to the pads 424 of the board 420 by an LMCA 430. The LMCA 430 may include a substrate 431 with wells 435. Liquid metal 432 may be provided in the wells 435. More generally, the volume of the liquid metal 432 within each of the wells 435 may be lower than the volume of the individual wells 435. As such, gaps 439 may be provided over and/or under the liquid metal 432. In an embodiment, the substrate 431 may be a low Poisson's ratio polymer, such as those described in greater detail above. For example, the substrate 431 may be an open cell elastomeric foam or the like with a Poisson's ratio of 0.2 or smaller or 0.1 or smaller. The liquid metal 432 may be a compressible liquid metal 432 similar to materials described in greater detail above. For example, voids (not shown) may be provided within the liquid metal 432 to enable sufficient compression. In the uncompressed state shown in FIG. 4A, the substrate 431 may have a first thickness T₁. The first thickness T₁ may be up to approximately 1,000 μm. Though, larger first thicknesses T₁ may also be used in some embodiments.

In an embodiment, one or more dies 405 may be provided over the package substrate 410. The die 405 may be coupled to the package substrate 410 through any FLI architecture, such as solder balls, copper bumps, hybrid bonding interfaces, or the like. A thermal solution 407, such as an integrated heat spreader or the like, may be thermally coupled to the die 405 in some embodiments.

Referring now to FIG. 4B, a cross-sectional illustration of the electronic system 400 in a compressed state is shown, in accordance with an embodiment. The compression results in the substrate 431 being reduced to a second thickness T₂ that is smaller than the first thickness T₁. The second thickness T₂ may be as small as 30% of the first thickness T₁, as small as 50% of the first thickness T₁, or as small as 80% of the first thickness T₁. However, due to the use of a low Poisson's ratio material for the substrate 431, the width of the wells 435 does not substantially change. For example, the width of the wells 435 in the compressed state may be within approximately 10% of the width of the wells 435 in an uncompressed state, within approximately 5% of the width of the wells 435 in an uncompressed state, or the same width of the wells 435 in an uncompressed state.

Additionally, the compressible nature of the liquid metal 432 allows for some reduction in volume for the liquid metal 432. The combination of substantially unchanging well 435 width and liquid metal 432 volume reduction reduces or eliminates the probability that the liquid metal 432 extrudes out from the wells 435. As such, there is a low (or essentially zero) chance that the liquid metal 432 produces shorting between interconnects.

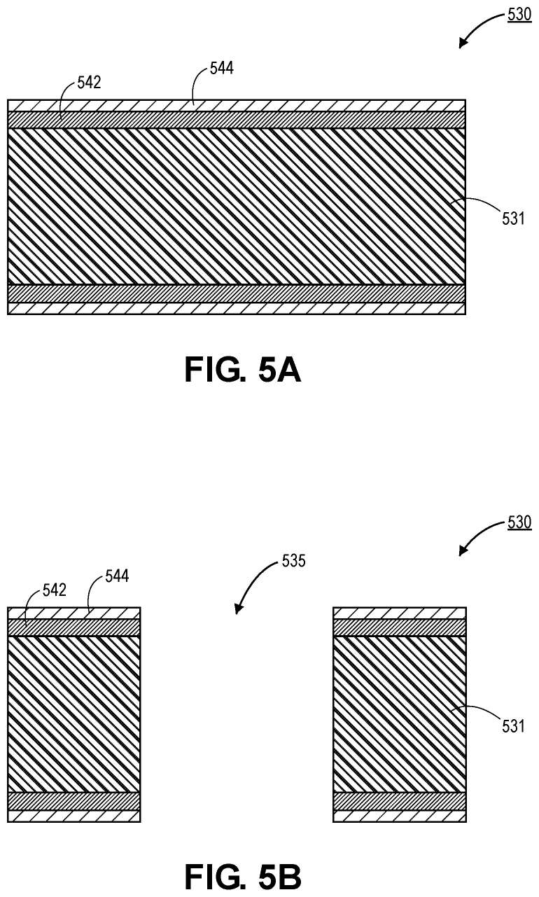

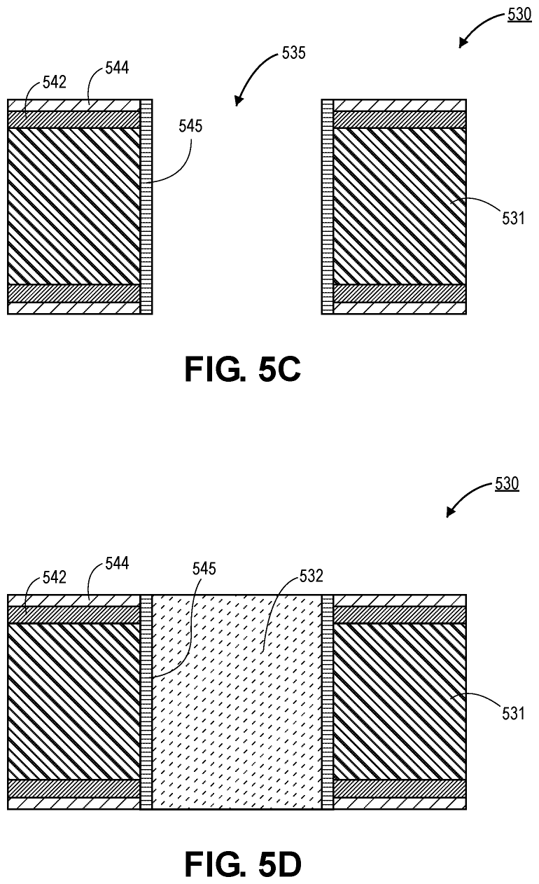

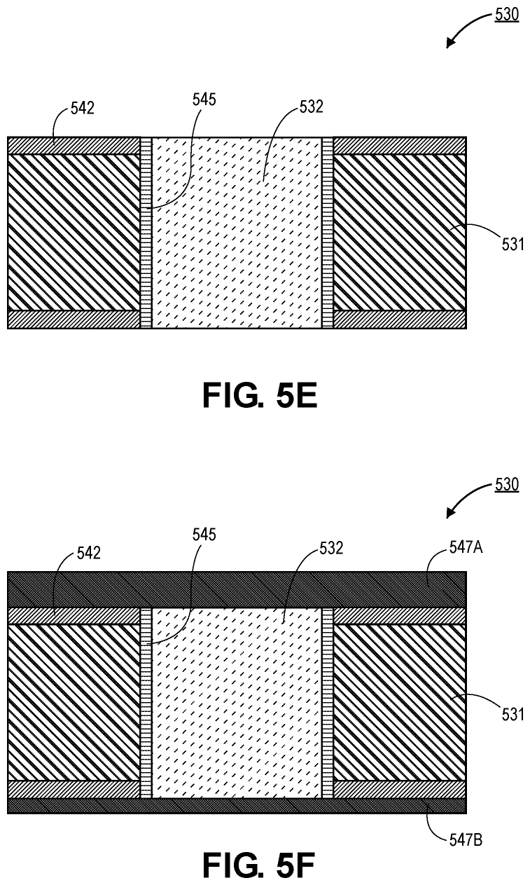

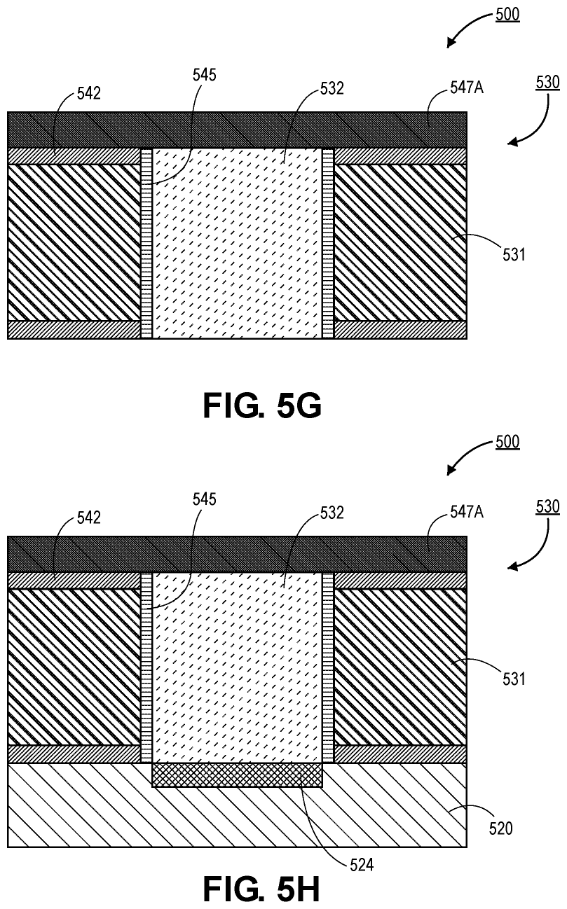

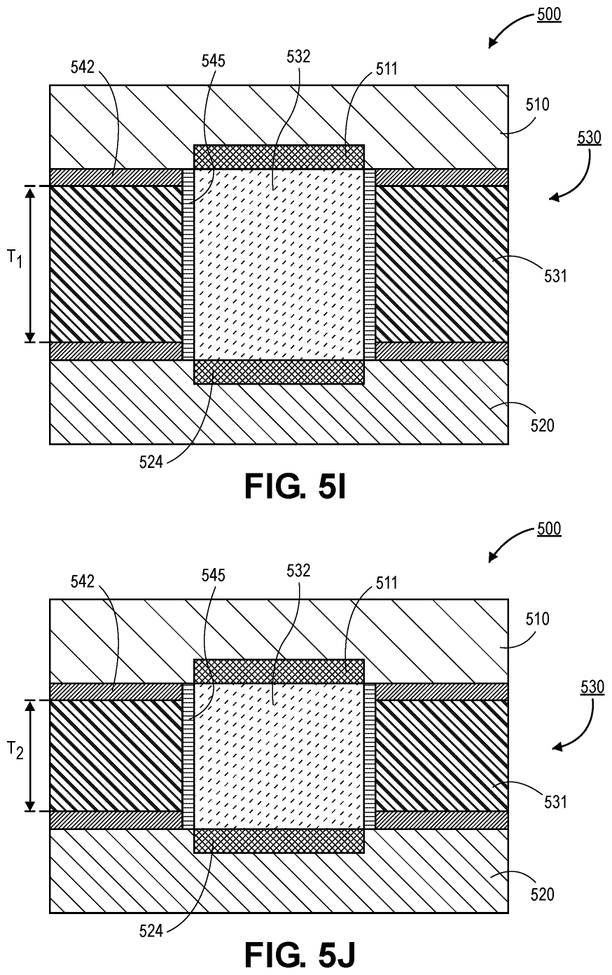

Referring now to FIGS. 5A-5J, a series of cross-sectional illustrations depicting a process for fabricating an LMCA 530 is shown, in accordance with an embodiment.

Referring now to FIG. 5A, a cross-sectional illustration of a LMCA 530 at a stage of manufacture is shown, in accordance with an embodiment. The LMCA 530 may include a substrate 531. The substrate 531 may be a low Poisson's ratio polymer. For example, the Poisson's ratio may be up to approximately 0.2 or up to approximately 0.1. In an embodiment, the substrate 531 may be a polymer foam, such as an elastomeric foam. The foam may be an open cell foam with up to 80% air by volume, up to 90% air by volume, or up to 95% air by volume. The substrate 531 may be similar to any of the low Poisson's ratio substrates described in greater detail herein. The substrate 531 may have a thickness that is up to approximately 1,000 μm. Though thicker substrates 531 may also be used in some embodiments.

In an embodiment, the substrate 531 may be covered by an adhesive 542. The adhesive 542 may be provided over a top surface and a bottom surface of the substrate 531. The adhesive 542 may be a glue like layer or other adhesive material used to couple the substrate 531 to other components (e.g., board and package substrate) in subsequent processing operations. The adhesives 542 may be covered by liners 544 in order to prevent adhesion to other components before necessary.

Referring now to FIG. 5B, a cross-sectional illustration of the substrate 530 at a stage of manufacture is shown, in accordance with an additional embodiment. As shown, a well 535 is provided through a thickness of the substrate 531. In some embodiments, the well 535 is formed with a die cutting process, a laser ablation process, or the like. In other embodiments, the well 535 may be formed at the time of substrate 531 fabrication with a molding process. The well 535 may have substantially vertical sidewalls. That is, the width of the well 535 may be substantially uniform through a thickness of the substrate 531. Though, in other embodiments, the well 535 may have tapered sidewalls or any shaped profile.

Referring now to FIG. 5C, a cross-sectional illustration of the LMCA 530 after a liner 545 is applied along sidewalls of the well 535 is shown, in accordance with an embodiment. In an embodiment, the liner 545 may be used in order to prevent the flow of liquid metal (not shown in FIG. 5C) into the volume of the substrate 531. The liner 545 may be any material that is substantially impervious to the flow of the liquid metal. In some embodiments, the liner 545 may be a polymer, such as an elastomer. In a particular embodiment, the liner 545 may be the same material as the substrate 531 without voids. That is, the liner 545 may not be a foam. For example, both the liner 545 and the substrate 531 may comprise silicone. The liner 545 may be applied with any suitable process, such as chemical vapor deposition (CVD), physical vapor deposition (PVD), lamination, or the like. The thickness of the liner 545 may be minimized in order to maintain a high volume of liquid metal in the well 535. For example, the liner 545 may have a thickness up to approximately 25um in some embodiments.

Referring now to FIG. 5D, a cross-sectional illustration of the LMCA 530 after the liquid metal 532 is deposited in the well 535 is shown, in accordance with an embodiment. In an embodiment, the liquid metal 532 may be deposited in the well 535 with any suitable deposition process, such as, printing, injection, or the like. In an embodiment, the liquid metal 532 may be similar to any of the liquid metal materials described in greater detail herein. For example, the liquid metal 532 may comprise gallium, indium, and any other suitable alloying element, such as tin. The liquid metal 532 may remain in a liquid phase at or around room temperature. In some instances the liquid metal 532 may remain in the liquid phase down to approximately −25° C. In an embodiment, the liquid metal 532 may be a compressible liquid metal 532. In order to provide the necessary compressibility, the liquid metal 532 may include voids (not shown). The voids may occupy between approximately 20% and approximately 50% of the liquid metal 532 by volume.

In the illustrated embodiment, the liquid metal 532 completely fills the well 535. Though, in other embodiments, the volume of the liquid metal 532 may partially fill the well 535. That is, gaps above and/or below the liquid metal 532 within the well 535 may be provided in some embodiments.

Referring now to FIG. 5E, a cross-sectional illustration of the LMCA 530 after the liners 544 are removed is shown, in accordance with an embodiment. In an embodiment, the liners 544 may be removed with any suitable process. For example, the liners 544 may be peeled away from the adhesive 542. Removal of the liners 544 exposes the adhesive 542 and allows for subsequent layers to be added to the LMCA 530.

Referring now to FIG. 5F, a cross-sectional illustration of the LMCA 530 after a second liner 547 is applied is shown, in accordance with an embodiment. In an embodiment, the second liner 547 may include a top liner 547A and a bottom liner 547B. The top liner 547A and the bottom liner 547B may have different thicknesses. For example, the top liner 547A may be thicker than the bottom liner 547B. The difference in thickness may be utilized in order to aid in subsequent assembly processes. For example, the different thicknesses may be used in order to indicate which liner 547A or 547B needs to be removed first.

Referring now to FIG. 5G, a cross-sectional illustration of the LMCA 530 after the bottom liner 547B is removed is shown, in accordance with an embodiment. The bottom liner 547B may be removed by peeling the bottom liner 547B off of the adhesive 542. Removal of the bottom liner 547B prepares the LMCA 530 for attachment to a board 520 in a subsequent processing operation.

Referring now to FIG. 5H, a cross-sectional illustration of an electronic system 500 after the LMCA 530 is attached to a board 520 is shown, in accordance with an embodiment. The board 520 may be a PCB, a motherboard, or the like. In an embodiment, the board 520 may include a pad 524. The pad 524 may be aligned with the liquid metal 532. As such, the LMCA 530 is electrically coupled to the pad 524 of the board 520. The adhesive 542 may mechanically couple the LMCA 530 to the board 520.

Referring now to FIG. 51, a cross-sectional illustration of the electronic system 500 after a package substrate 510 is attached to the LMCA 530 is shown, in accordance with an embodiment. In an embodiment, the LMCA 530 may have the top liner 547A removed in order to expose the adhesive 542. The adhesive 542 mechanically couples the LMCA 530 to the package substrate 510. In an embodiment, a pad 511 of the package substrate 510 may be aligned over the liquid metal 532. As such, the liquid metal 532 of the LMCA 530 electrically couples the pad 524 of the board 520 to the pad 511 of the package substrate 510.

In FIG. 5I, the LMCA 530 is uncompressed. As such, the substrate 531 has a first thickness T₁. The first thickness T₁ may be up to approximately 1,000 μm in some embodiments. Though, thicker substrates 531 may also be used in some embodiments.

Referring now to FIG. 5J, a cross-sectional illustration of the electronic system 500 after compression is shown, in accordance with an embodiment. The compression may be provided by a retention mechanism (not shown). In an embodiment, the compression may result in the LMCA 530 being reduced in thickness. For example, the substrate 531 may have a second thickness T₂ that is smaller than the first thickness T₁. The second thickness T₂ may be up to approximately 80% of the first thickness T₁, or the second thickness T₂ may be up to approximately 50% of the first thickness T₁. Due to the low Poisson's ratio of the substrate 531, the reduction in thickness in the Z-direction may not significantly alter the width of the well 535, similar to embodiments described in greater detail above. Further, the compressibility of the liquid metal 532 may aid in the prevention of extrusion of the liquid metal 532 outside of the well 535.

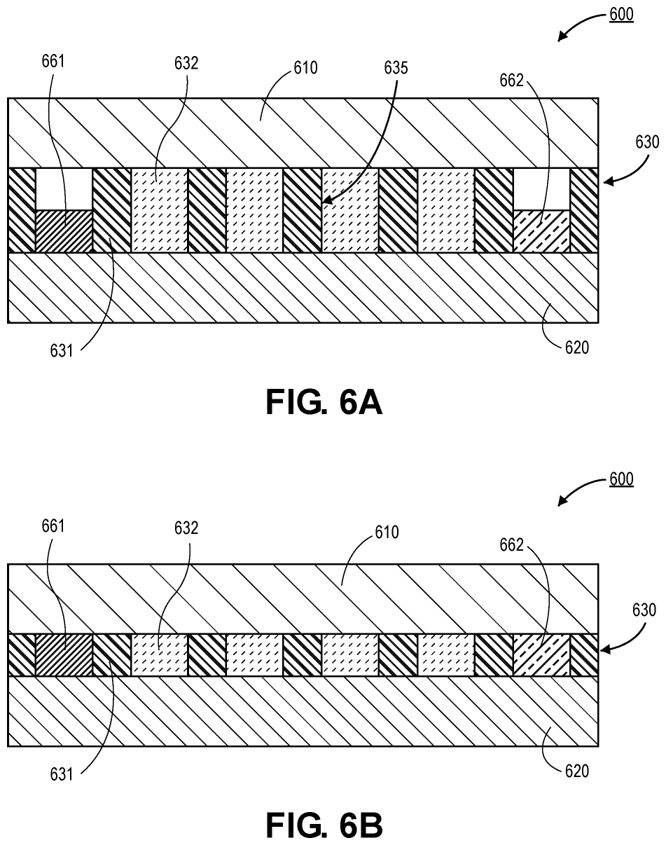

Referring now to FIG. 6A, a cross-sectional illustration of an electronic system 600 is shown, in accordance with an embodiment. In an embodiment, the electronic system 600 may comprise a board 620, a package substrate 610, and an LMCA 630 between the board 620 and the package substrate 610. In an embodiment, the LMCA 630 may comprise a substrate 631 with wells 635. Liquid metal 632 may be provided in at least one of the wells 635. The substrate 631 and the liquid metal 632 may be similar to any of the low Poisson's ratio substrates or compressible liquid metals described in greater detail herein.

In an embodiment, at least one of the wells 635 may also include a standoff feature 661. The standoff feature 661 may be substantially non-compressible. As such, when the LMCA 630 is compressed, the compression is stopped at the top of the standoff feature 661. The standoff feature 661 may comprise a polymer, a metal, or the like. Additionally, one or more of the wells 635 may include an adhesive 662. The adhesive 662 may have a thickness that is substantially similar to that of the standoff feature 661.

Referring now to FIG. 6B, a cross-sectional illustration of the electronic system 600 after compression is shown, in accordance with an embodiment. As shown, the compression results in the package substrate 610 being pressed down so that the package substrate 610 contacts the standoff feature 661. Additionally, the adhesive 662 is brought into contact with the package substrate 610. This prevents the substrate 631 from expanding again. As such, there may not be a need for an external retention mechanism. This saves space and reduces cost of the electronic system 600.

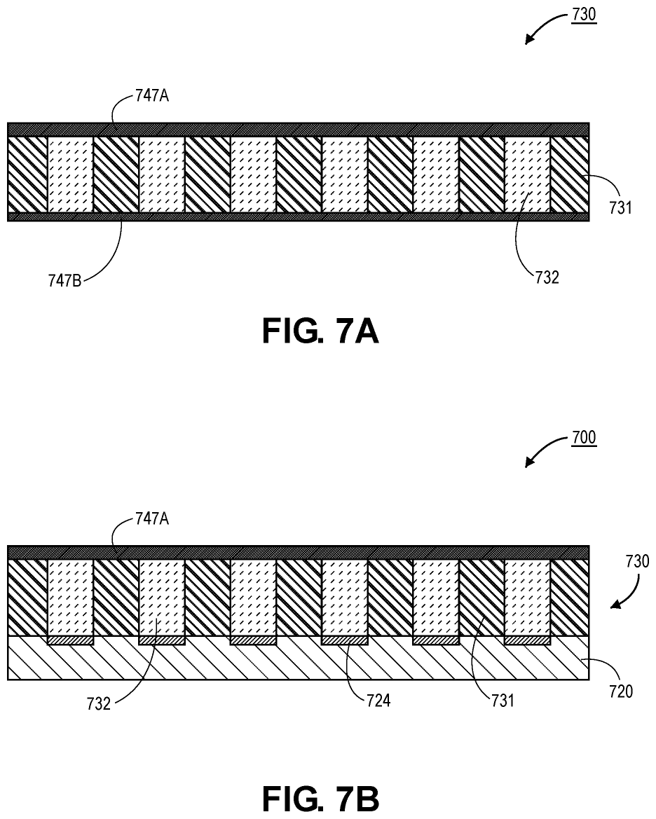

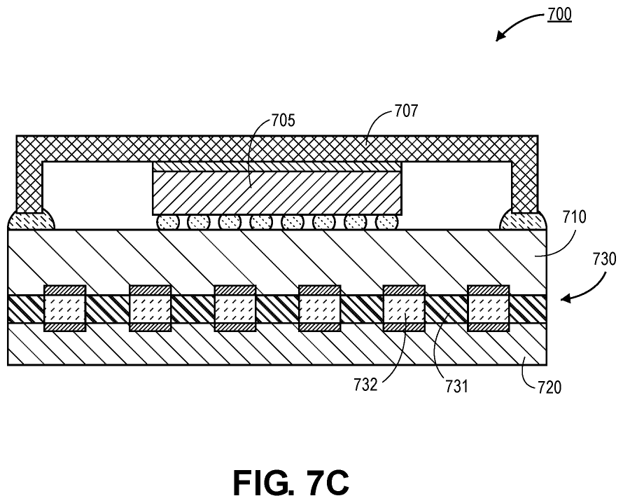

Referring now to FIGS. 7A-7C, a series of cross-sectional illustrations depict various components and systems that may be sold in various configurations. That is, the LMCA architectures described herein provide enhanced flexibility for where and when the LMCA is implemented in order to satisfy the needs of various vendors and suppliers.

Referring now to FIG. 7A, a cross-sectional illustration of an LMCA 730 by itself is shown, in accordance with an embodiment. The LMCA 730 may include a substrate 731 that is a low Poisson's ratio material, such as those described in greater detail herein. Liquid metal 732 may be provided in wells through the substrate 731. The liquid metal 732 may be a compressible liquid metal 732 similar to other liquid metals described in greater detail herein. In order to enable shipping and handling of the LMCA 730, liners 747A and 747B may be provided over and under the substrate 731. The top liner 747A may have a different thickness than the bottom liner 747B in order to help orient the LMCA 730 for subsequent assembly operations.

Referring now to FIG. 7B, a cross-sectional illustration of an electronic system 700 is shown, in accordance with an embodiment. As shown, the LMCA 730 is coupled to the board 720 so that liquid metal 732 is aligned over pads 724. The LMCA 730 may be adhered to the board 720 by an adhesive (not shown). The top liner 747A may remain in order to allow for shipping and handling without damaging the electronic system 700.

Referring now to FIG. 7C, a cross-sectional illustration of an electronic system 700 is shown, in accordance with an additional embodiment. The electronic system 700 in FIG. 7C is similar to the one in FIG. 7B, with the addition of a package substrate 710. An adhesive (not shown) may attach the LMCA 730 to the package substrate 710. One or more dies 705 and a thermal solution 707 (e.g., an integrated heat spreader) may also be provided in the electronic system 700.

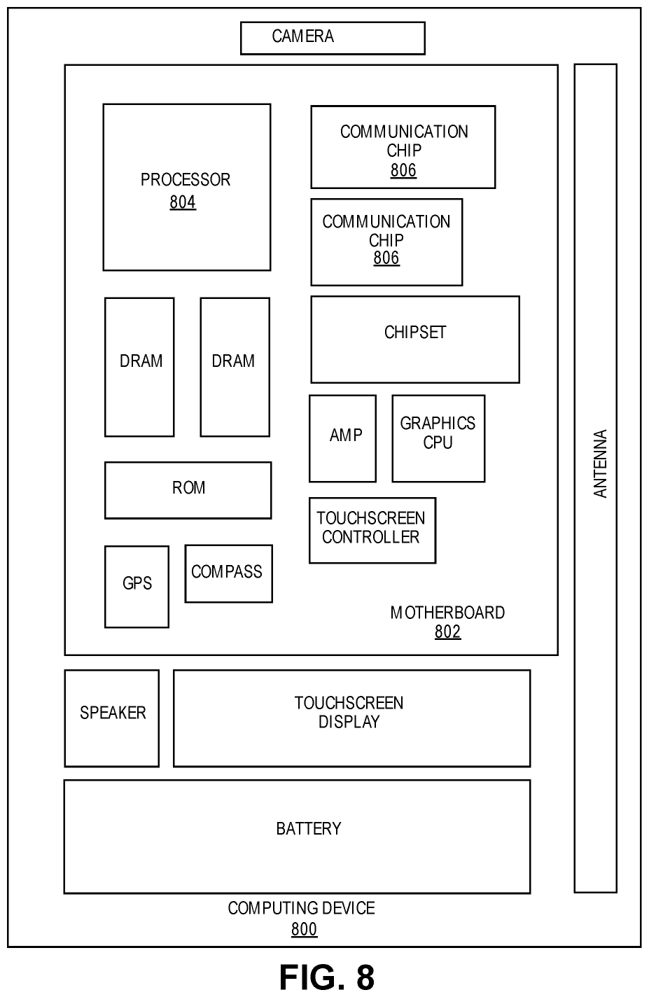

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor may be part of an electronic package that includes an LMCA with a low Poisson's ratio substrate and a compressible liquid metal, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the disclosure, the integrated circuit die of the communication chip may be part of an electronic package that includes an LMCA with a low Poisson's ratio substrate and a compressible liquid metal, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate with a well through a thickness of the substrate, wherein the substrate comprises a polymer foam; and a liquid metal in the opening, wherein the liquid metal comprises voids.

Example 2: the apparatus of Example 1, wherein the polymer foam comprises up to 95% air by volume.

Example 3: the apparatus of Example 1 or Example 2, wherein the polymer foam is an open cell foam.

Example 4: the apparatus of Examples 1-3, wherein the well has a first width when the substrate has an uncompressed thickness and a second width when the substrate is compressed in a thickness direction up to 50% of the uncompressed thickness, and wherein a difference between the first width and the second width is within 5%.

Example 5: the apparatus of Example 4, wherein the first width is the same as the second width.

Example 6: the apparatus of Examples 1-5, wherein the voids account for up to 50% of the liquid metal by volume.

Example 7: the apparatus of Examples 1-6, further comprising: a liner along sidewalls of the opening.

Example 8: the apparatus of Example 7, wherein the liner comprises a rubber material.

Example 9: the apparatus of Examples 1-8, further comprising: a first layer over the substrate and the well; and a second layer under the substrate and the well.

Example 10: the apparatus of Example 9, wherein the first layer has a first thickness and the second layer has a second thickness that is smaller than the first thickness.

Example 11: an apparatus, comprising: a board; and an interconnect layer over the board, wherein the interconnect layer comprises: a substrate, wherein the substrate comprises an open cell elastomer foam; wells through a thickness of the substrate; and a liquid metal provided in one or more of the wells, wherein voids are provided within a volume of the liquid metal.

Example 12: the apparatus of Example 11, wherein the substrate has a Poisson's ratio of less than 0.2.

Example 13: the apparatus of Example 12, wherein the Poisson's ratio is less than 0.1.

Example 14: the apparatus of Examples 11-13, wherein the voids occupy up to 50% of the volume of the liquid metal.

Example 15: the apparatus of Examples 11-14, further comprising: a standoff feature in a first well, wherein a thickness of the standoff feature is less than a thickness of the substrate; and an adhesive in a second well.

Example 16: the apparatus of Examples 11-15, further comprising: a liner on sidewalls of wells.

Example 17: an apparatus, comprising: a board; an interconnect layer over the board, wherein the interconnect layer comprises: a substrate with openings through the substrate, wherein the substrate has a Poisson's ratio of less than 0.2; and a liquid metal in the openings, wherein the liquid metal is compressible; and a package over the interconnect layer, wherein the package comprises: a package substrate; and a die on the package substrate.

Example 18: the apparatus of Example 17, wherein the liquid metal comprises voids.

Example 19: the apparatus of Example 17 or Example 18, wherein the substrate comprises an open cell polymer foam.

Example 20: the apparatus of Examples 17-19, wherein the apparatus is part of a personal computer, a server, a mobile device, a tablet, or an automobile.

What is claimed is:

1. An apparatus, comprising:
a substrate with a well through a thickness of the substrate, wherein the substrate comprises a polymer foam; and
a liquid metal in the opening, wherein the liquid metal comprises voids.

2. The apparatus of claim 1, wherein the polymer foam comprises up to 95% air by volume.

3. The apparatus of claim 1, wherein the polymer foam is an open cell foam.

4. The apparatus of claim 1, wherein the well has a first width when the substrate has an uncompressed thickness and a second width when the substrate is compressed in a thickness direction up to 50% of the uncompressed thickness, and wherein a difference between the first width and the second width is within 5%.

5. The apparatus of claim 4, wherein the first width is the same as the second width.

6. The apparatus of claim 1, wherein the voids account for up to 50% of the liquid metal by volume.

7. The apparatus of claim 1, further comprising:
a liner along sidewalls of the opening.

8. The apparatus of claim 7, wherein the liner comprises a rubber material.

9. The apparatus of claim 1, further comprising:
a first layer over the substrate and the well; and
a second layer under the substrate and the well.

10. The apparatus of claim 9, wherein the first layer has a first thickness and the second layer has a second thickness that is smaller than the first thickness.

11. An apparatus, comprising:
a board; and
an interconnect layer over the board, wherein the interconnect layer comprises:
a substrate, wherein the substrate comprises an open cell elastomer foam;
wells through a thickness of the substrate; and
a liquid metal provided in one or more of the wells, wherein voids are provided within a volume of the liquid metal.

12. The apparatus of claim 11, wherein the substrate has a Poisson's ratio of less than 0.2.

13. The apparatus of claim 12, wherein the Poisson's ratio is less than 0.1.

14. The apparatus of claim 11, wherein the voids occupy up to 50% of the volume of the liquid metal.

15. The apparatus of claim 11, further comprising:
a standoff feature in a first well, wherein a thickness of the standoff feature is less than a thickness of the substrate; and
an adhesive in a second well.

16. The apparatus of claim 11, further comprising:
a liner on sidewalls of wells.

17. An apparatus, comprising:
a board;
an interconnect layer over the board, wherein the interconnect layer comprises:
a substrate with openings through the substrate, wherein the substrate has a Poisson's ratio of less than 0.2; and
a liquid metal in the openings, wherein the liquid metal is compressible; and
a package over the interconnect layer, wherein the package comprises:
a package substrate; and
a die on the package substrate.

18. The apparatus of claim 17, wherein the liquid metal comprises voids.

19. The apparatus of claim 17, wherein the substrate comprises an open cell polymer foam.

20. The apparatus of claim 17, wherein the apparatus is part of a personal computer, a server, a mobile device, a tablet, or an automobile.
